(19) United States
(12) Patent Application Publication
(10) Pub. No.: US 2023/0422402 A1
(43) Pub. Date: Dec. 28, 2023

(54) Lift Printing of Fine Metal Lines

(71) Applicant: Orbotech Ltd., Yavne (IL)

(72) Inventors: Sharona Cohen, Nof Ayalon (IL); Ofer Fogel, Jerusalem (IL); Zvi Kotler, Tel Aviv (IL)

(21) Appl. No.: 18/039,116

(22) PCT Filed: Jun. 22, 2021
(86) PCT No.: PCT/IB2021/055475

§ 371 Date: May 26, 2023

Related U.S. Application Data
(60) Provisional application No. 63/130,854, filed on Dec. 28, 2020.

(51) Int. Cl. H05K 3/10; H05K 1/16; H05K 3/14

(52) U.S. Cl. CPC H05K 3/102; H05K 1/167; H05K 3/14; H05K 2203/107; H05K 2203/1344

(57) ABSTRACT

A method for circuit fabrication includes defining a locus of a conductive trace to be formed on a circuit substrate. Molten droplets of a metal are ejected from a donor substrate in proximity to the circuit substrate onto the defined locus by a process of laser-induced forward transfer (LIFT), whereby the droplets adhere to and harden on the circuit substrate along a length of the defined locus. After the droplets have hardened, a laser beam is directed toward the defined locus with sufficient energy to cause the metal in the hardened droplets to melt and coalesce into a bulk layer extending along the length of the defined locus.

### CROSS-REFERENCE TO RELATED APPLICATIONS

This application claims priority to the provisional patent application filed Dec. 28, 2020 and assigned U.S. App. No. 63/130,854, the disclosure of which is hereby incorporated by reference.

### FIELD OF THE INVENTION

The present invention relates generally to fabrication of electronic devices, and particularly to methods and systems for printing conductive lines on a substrate.

### BACKGROUND

In laser direct-write (LDW) techniques, a laser beam is used to create a patterned surface with spatially-resolved three-dimensional structures by controlled material ablation or deposition. Laser-induced forward transfer (LIFT) is an LDW technique that can be applied in depositing micro-patterns on a surface.

In LIFT, laser photons provide the driving force to catapult a small volume of material from a donor film toward an acceptor substrate. Typically, the laser beam interacts with the inner side of the donor film, which is coated onto a non-absorbing carrier substrate. The incident laser beam, in other words, propagates through the transparent carrier substrate before the photons are absorbed by the inner surface of the film. Above a certain energy threshold, material is ejected from the donor film toward the surface of the acceptor substrate. Given a proper choice of donor film and laser beam pulse parameters, the laser pulses cause molten droplets of the donor material to be ejected from the film, and then to land and harden on the acceptor substrate.

LIFT systems are particularly (though not exclusively) useful in printing conductive metal droplets and traces for purposes of electronic circuit fabrication. A LIFT system of this sort is described, for example, in U.S. Pat. No. 9,925,797, whose disclosure is incorporated herein by reference. This patent describes printing apparatus, including a donor supply assembly, which is configured to provide a transparent donor substrate having opposing first and second surfaces and a donor film formed on the second surface so as to position the donor film in proximity to a target area on an acceptor substrate. An optical assembly is configured to direct multiple output beams of laser radiation simultaneously in a predefined spatial pattern to pass through the first surface of the donor substrate and impinge on the donor film so as to induce ejection of material from the donor film onto the acceptor substrate according, thereby writing the predefined pattern onto the target area of the acceptor substrate.

LIFT printing can also be used to repair defects in printed circuit traces. Systems and methods for this purpose are described, for example, in Korean Patent Application Publication KR20150070028, whose disclosure is incorporated herein by reference.

In addition, LIFT systems can be used in direct printing of embedded resistors onto a substrate. For example, PCT International Publication WO 2019/138404, whose disclosure is incorporated herein by reference, describes a method for fabrication of an electrical device which includes identifying a locus on a circuit substrate on which a resistor having a specified resistance is to be formed between first and second endpoints of the locus. A transparent donor substrate, having opposing first and second surfaces and a donor film comprising a resistive material formed over the second surface, is positioned in proximity to the identified locus on the circuit substrate, with the second surface facing toward the circuit substrate. Pulses of laser radiation are directed to impinge on the donor film so as to induce ejection of droplets of the resistive material from the donor film onto the circuit substrate at respective, neighboring locations along the locus with a separation between the neighboring locations selected so as to form a circuit trace having the specified resistance between the first and second endpoints.

### SUMMARY

Embodiments of the present invention that are described hereinbelow provide novel methods and systems for LIFT-based fabrication of metal traces on a substrate, as well as circuits produced by such methods.

There is therefore provided, in accordance with an embodiment of the invention, a method for circuit fabrication, which includes defining a locus of a conductive trace to be formed on a circuit substrate. Droplets of a metal are ejected from a donor substrate in proximity to the circuit substrate onto the defined locus by a process of laser-induced forward transfer (LIFT), whereby the droplets adhere to and harden on the circuit substrate along a length of the defined locus. After the droplets have hardened, a laser beam is directed toward the defined locus with sufficient energy to cause the metal in the hardened droplets to melt and coalesce into a bulk layer extending along the length of the defined locus.

In some embodiments, the donor substrate is transparent and has opposing first and second surfaces, and a donor film including the metal is disposed on the second surface such that the donor film is in proximity to the defined locus, and ejecting the molten droplets includes directing pulses of laser radiation to pass through the first surface of the donor substrate and impinge on the donor film so as to induce ejection from the donor film onto the defined locus of the molten droplets of the metal.

In one embodiment, directing the pulses of laser radiation in the process of LIFT and directing the laser beam toward the defined locus include using a single laser having a variable pulse duration for both ejecting the molten droplets and melting the metal in the hardened droplets.

Alternatively or additionally, the donor film includes a first metal, and an adhesion film, including a second metal is disposed over the donor film on the donor substrate, so that the second metal forms an outer layer over the molten droplets of the first metal, and the outer layer adheres to the circuit substrate upon impact of the molten droplets on the circuit substrate. In a disclosed embodiment, the first metal includes copper, and the second metal is selected from a group consisting of titanium, tin, bismuth, and alloys thereof.

In some embodiments, ejecting the molten droplets and directing the laser beam toward the defined locus include ejecting a first layer of the molten droplets onto the circuit substrate and directing the laser beam to melt the hardened droplets in the first layer so as to form a lower layer of the conductive trace, and ejecting at least a second layer of the molten droplets onto the lower layer and directing the laser beam to melt the hardened droplets in the at least second layer so as to complete the conductive trace.

In one embodiment, directing the laser beam includes applying sufficient energy to the hardened droplets, using the laser beam, to melt an entire volume of the hardened droplets in the conductive trace. Alternatively, directing the laser beam includes applying sufficient energy to the hardened droplets, using the laser beam, to melt only an outer layer of the hardened droplets, without melting an entire volume of the hardened droplets along the length of the defined locus. Typically, the outer layer forms a protective skin, which encloses the volume of the hardened droplets within the conductive trace.

In the disclosed embodiments, directing the laser beam includes directing a sequence of pulses of laser energy to impinge on the hardened droplets along the length of the defined locus. In some of these embodiments, each of the pulses has a pulse duration that is less than 10 μs and may be no greater than 1 μs. Alternatively or additionally, directing the one or more pulses includes scanning the laser beam along the locus, such that each of the pulses has a predefined overlap with a preceding pulse in the sequence.

In some embodiments, ejecting the molten droplets includes depositing the droplets on the circuit substrate in a single row extending along the length of the defined locus, whereby the conductive trace is formed by melting of the single row. In one such embodiment, each droplet overlaps a preceding droplet in the single row by no more than 50% of a diameter of the droplet.

In further embodiments, defining the locus includes identifying a gap between first and second terminals on the circuit substrate, and ejecting the molten droplets includes depositing the molten droplets so as to fill the gap. In one embodiment, the first and second terminals include a first metal, and the droplets include a second metal, of a different composition from the first metal, and directing the laser beam includes melting the first and second metals so as to form heterogeneous metal bonds at the first and second terminals. Alternatively, identifying the gap includes detecting a defect in a circuit trace that has been formed on the circuit substrate, and the defect is repaired by depositing the molten droplets and then directing the laser beam to melt the hardened droplets.

In a disclosed embodiment, the locus has a predefined width, and directing the laser beam includes melting only the hardened droplets that have been deposited on the circuit substrate within the predefined width of the locus, wherein the method includes applying an etching process, after directing the laser beam, so as to remove the hardened droplets that were deposited on the circuit substrate outside the predefined width of the locus.

There is also provided, in accordance with an embodiment of the invention, apparatus for fabrication of a conductive trace on a circuit substrate. The apparatus includes a deposition module, which is configured to eject molten droplets of a metal from a donor substrate in proximity to the circuit substrate onto a defined locus of the conductive trace by a process of laser-induced forward transfer (LIFT), whereby the droplets adhere to and harden on the circuit substrate along a length of the defined locus. A laser module is configured to direct a laser beam toward the defined locus with sufficient energy to cause the metal in the hardened droplets to melt and coalesce into a bulk layer extending along the length of the defined locus.

The present invention will be more fully understood from the following detailed description of the embodiments thereof, taken together with the drawings in which:

### BRIEF DESCRIPTION OF THE DRAWINGS

FIG. 1 is schematic side view of a system for printing conductive traces on a substrate, in accordance with an embodiment of the invention;

FIG. 2A is a photomicrograph of a line of metal droplets printed on a substrate, in accordance with an embodiment of the invention;

FIG. 2B is a photomicrograph of the line of FIG. 2A following laser melting, in accordance with an embodiment of the invention;

FIG. 3 is a schematic sectional view of a donor film, illustrating ejection of a molten droplet from the film under laser irradiation, in accordance with an embodiment of the invention;

FIG. 4A is a schematic sectional view of an aggregation of metal droplets deposited on a substrate in a LIFT process, defining a circuit trace in accordance with an embodiment of the invention;

FIG. 4B is a schematic sectional view of a circuit trace formed by full laser melting of the aggregation of metal droplets of FIG. 4A, in accordance with an embodiment of the invention;

FIG. 4C is a schematic sectional view of a circuit trace formed by partial laser melting of the aggregation of metal droplets of FIG. 4A, in accordance with an alternative embodiment of the invention;

FIG. 5A is a schematic sectional view of an aggregation of metal droplets deposited by a LIFT process in a gap in a circuit trace, in accordance with an embodiment of the invention;

FIG. 5B is a schematic sectional view of the aggregation of FIG. 5A illustrating an application of a laser melting process to the aggregation, in accordance with an embodiment of the invention;

FIG. 5C is a schematic sectional view of a circuit trace formed by the laser melting process of FIG. 5B, in accordance with an embodiment of the invention;

FIG. 6A is a schematic sectional view illustrating an application of a laser melting process to an aggregation of metal droplets deposited by a LIFT process in a gap in a circuit trace, in accordance with an embodiment of the invention;

FIG. 6B is a schematic sectional view of a partial circuit trace formed by the laser melting process of FIG. 6A, in accordance with an embodiment of the invention;

FIG. 6C is a schematic sectional view illustrating an application of a laser melting process to an aggregation of metal droplets deposited by a LIFT process over the partial circuit trace of FIG. 6B, in accordance with an embodiment of the invention;

FIG. 6D is a schematic sectional view of a full circuit trace formed by the laser melting process of FIG. 6C, in accordance with an embodiment of the invention;

FIG. 7 is a schematic sectional view of a heterogeneous circuit trace printed by a LIFT process, in accordance with an embodiment of the invention; and

FIGS. 8A, 8B, 8C, 8D and 8E are schematic top views of a circuit trace on a subject showing successive steps in a LIFT-base process of repairing a gap in the circuit trace, in accordance with an alternative embodiment of the invention.

### DETAILED DESCRIPTION OF EMBODIMENTS

### Overview

LIFT processes are capable of printing conductive traces and other circuit components on circuit substrates with high precision and speed. Due to the nature of the LIFT process, however, the resulting traces are made up of an aggregation of metal grains, corresponding to the hardened droplets that were ejected onto the substrate. These grains are typically covered and separated by a thin oxidation layer, and there may be voids and air pockets interspersed between the grains. These phenomena tend to increase the electrical resistance and compromise the mechanical integrity of the circuit traces, by comparison with solid metal traces that are deposited using more conventional methods.

Embodiments of the present invention that are described herein address these problems by adding a stage of controlled laser melting in the deposition process. In these embodiments, after defining the locus of a conductive trace to be formed on a circuit substrate, a LIFT process is applied to eject molten droplets of a metal from a donor substrate in proximity to the circuit substrate onto the defined locus. (The “locus” typically comprises a line of a specified width extending between two endpoints, for example between a pair of metal terminals on the substrate; but traces extending along loci of other shapes may similarly be defined and fabricated.) The droplets adhere to and harden on the circuit substrate along the length of the locus of the trace, but at this stage still retain their separate grain structure.

Therefore, after the droplets have hardened, a laser beam is directed toward the locus of the trace with sufficient energy to cause the metal in the hardened droplets to melt and coalesce into a bulk layer, which extends along the length of the defined locus. The terms “coalesce” and “bulk layer” are used in the context of the present description and in the claims to refer to a layer in which the boundaries between the hardened droplets are appreciably reduced in size and distribution in comparison to the boundaries prior to melting. For example, in some embodiments, at least 50% of the boundaries that were present between the hardened droplets after LIFT deposition but before laser melting are no longer appreciable under microscopic inspection after laser melting.

In the disclosed embodiments, the laser beam is pulsed, and a sequence of pulses of laser energy is applied along the length of the locus. The use of pulsed radiation is advantageous in concentrating the resulting heat locally within the metal of the trace and minimizing heat loss and possible damage by conduction of heat from the trace to the circuit substrate. Depending on the thickness and width of the trace, the pulse duration may be less than 10 μs, or even less than 1 μs for narrow traces. For example, in one embodiment, the metal droplets may be deposited on the circuit substrate in a single row extending along the length of the defined locus, with a predefined overlap between the droplets. Short laser pulses are then applied to cause the hardened droplets to melt and coalesce into a circuit trace with a width of 10 μs, or even less.

The controlled laser melting process provided by embodiments of the present invention may be applied to the entire volume of the hardened droplets in the trace (particularly when the trace is thin, as in the example described above). Alternatively, the laser melting may be applied only to an outer layer of the hardened droplets, thus forming a protective “skin,” which encloses the remaining volume of the trace. In either case, the controlled laser melting process improves both the mechanical and electrical integrity of the resulting trace. In some cases, the melting process also improves the adhesion of the trace to the substrate and its ability to withstand subsequent etching steps. The present techniques may also be applied at the ends of the locus, where the LIFT-printed circuit trace makes contact with existing terminals on the circuit substrate, thus strengthening the electrical and mechanical connections between the trace and the terminals. This sort of controlled laser melting can be used to form heterogeneous metal bonds when the terminals and the droplets comprise different metal compositions.

### System Description

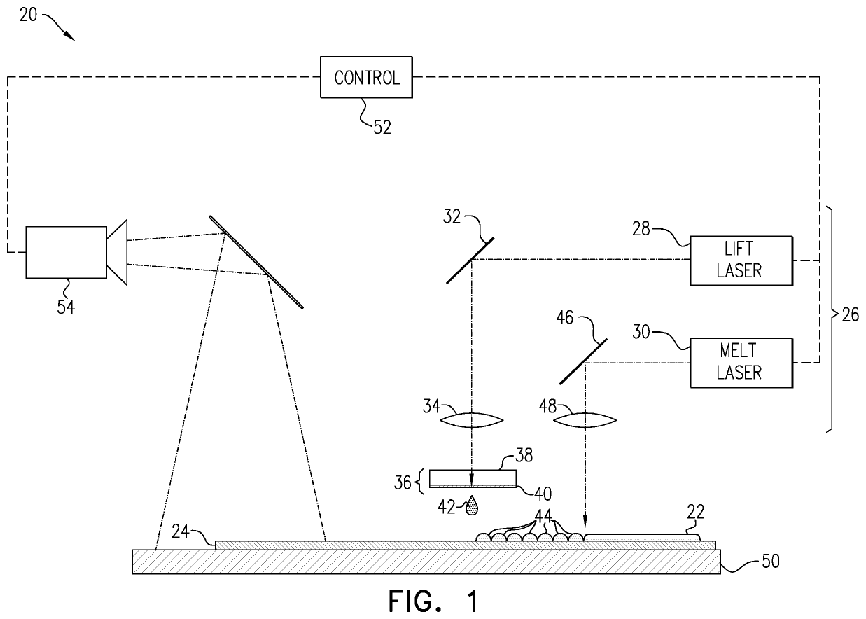

FIG. 1 is schematic side view of a system 20 for printing a conductive trace 22 on a substrate 24, in accordance with an embodiment of the invention. Substrate 24 may comprise any suitable sort of circuit substrate that is known in the art, such as semiconductor, ceramic, metal, organic, and other dielectric substrates, as are known in the art. Substrate 24 may be either rigid or flexible; and the techniques that are described herein are particularly well suited, inter alia, to printing of circuit traces and other conductive structures on delicate substrates that may not tolerate the heat and corrosive chemicals that are normally used in printed circuit fabrication. During the printing process, substrate 24 is held on a suitable mount, for example an adjustable mount such as a translation stage 50.

System 20 comprises a laser module 26, including one or more lasers and suitable optics for directing an appropriate laser beam or beams toward substrate 24. In the pictured embodiment, laser module 26 includes both a LIFT laser 28 and a melt laser 30. For the sake of simplicity, the functions and properties of these lasers are described here as though the lasers were separate units (which is one possible implementation of laser module 26). Alternatively, a single laser, emitting short, high-energy pulses with a variable pulse duration, may perform the functions of both LIFT laser 28 and melt laser 30. Lasers 28 and 30 emit optical radiation in the visible, ultraviolet, and/or infrared ranges at suitable wavelengths and with suitable temporal pulse lengths and focal qualities to perform the functions that are described herein, as detailed further in the description below.

Control circuitry 52 controls the operation of laser module 26, as well as of other elements of system 20, either autonomously or under the control of a human operator. For purposes of evaluation and alignment of the printing process with features on substrate 24, an inspection module 54, comprising one or more optical sensors, may be incorporated in system 20 in order to capture images of the substrate and pass the image data to control circuitry 52 for analysis. Control circuitry 52 typically comprises a general-purpose computer processor, which is programmed in software to carry out the functions that are described herein, along with suitable interfaces for communicating with and controlling the other components of system 20. Alternatively or additionally, at least some of the functions of control circuitry 32 may be carried out by a digital signal processor (DSP) or hardware logic components, which may be hard-wired or programmable.

LIFT laser 28 emits short pulses, with pulse duration typically on the order of 1 ns, toward a donor assembly 36 under the control of control circuitry 52. Donor assembly 36 serves as a deposition module, ejecting molten droplets 42 of a metal onto the defined locus of conductive trace 22 by a LIFT process driven by LIFT laser 28. Donor assembly 36 comprises a donor substrate 38, which typically comprises a thin, flexible sheet of a transparent material, which is coated on the side in proximity to circuit substrate 24 with a donor film 40 comprising a specified metal or combination of metals. (The donor film may including sub-layers, such as an adhesion film, as described hereinbelow with reference to FIG. 3.) Alternatively, donor substrate 38 may comprise a rigid or semi-rigid material. A beam deflector 32, such as a rotating mirror and/or an acousto-optic device, and focusing optics 34 direct the pulses of radiation from LIFT laser 28 to pass through the upper surface of donor substrate 38 and thus impinge on donor film 40 on the lower surface, in accordance with a spatial pattern determined by control circuitry 52.

Each laser pulse induces the ejection of one or more molten droplets 42 of metal from donor film 40 onto substrate 24. The duration and energy of the laser pulses (typically with pulse duration in the nanosecond range) and the thickness of donor film 40 can be chosen so that each laser pulse causes a single molten droplet 42 to be ejected from the donor film toward circuit substrate with accurate directionality and high speed. Further details of this sort of LIFT operation are described in the above-mentioned U.S. Pat. No. 9,925,797. Droplets 42 adhere to and harden on the substrate, thus defining, in the pictured example, a line of hardened droplets 44. Each droplet adds a certain amount of metal material to the line. Control circuitry 52 sets the number of droplets to deposit and the spacing between successive droplets depending on the desired thickness of line 22. Thus, to create a very thin line, droplets 42 may be deposited with only partial overlap between successive droplets, so that the width and height of line 22 will be approximately equal to the width and height of a single droplet 44. Using this approach, it is possible to create very fine lines, with widths down to the micron range. Alternatively, thicker aggregations of droplets 44 may be used to create wider, deeper lines.

After deposition of droplets 44, melt laser 30 irradiates the line of droplets with sufficient energy to cause the metal to melt, so that the droplets fuse together into a bulk material along line 22. A beam deflector 46, such as a scanning mirror and/or an acousto-optic device, and focusing optics 48 direct the radiation from melt laser 30 to impinge on the target line. The beam energy and other parameters of melt laser 30 are selected so as to melt the metal in droplets 44 while minimizing thermal damage to substrate 24 and surrounding structures. The beam may be sufficiently energetic to melt the entire volume of the line, or to melt only a part of the volume (for example, to fuse an outer skin of a thick volume of droplets, without necessarily melting the entire volume).

In some embodiments, melt laser 30 emits a sequence of pulses of laser energy, rather than a CW beam, in order to ensure that the thermal effects of the melting steps are well localized, with minimal effect on substrate 24 and surrounding structures. The use of short pulses is also beneficial in preventing the metal droplets from coalescing into balls, so that the trace maintains the desired shape. Optics 48 focus the beam to impinge on the target line with a beam diameter that is small enough so as not to melt neighboring structures. For this purpose, the beam diameter may be less than the line width. The beam diameter is sufficiently large, however, to melt the entire area of the locus of the trace that has been covered with droplets 44. Beam deflector 46 scans the beam of melt laser 30 along the locus of trace 22 such that each of the pulses has a predefined overlap with a preceding pulse in the sequence. The scan rate is adjusted so that the appropriate thermal dosage is applied uniformly along the entire trace.

Typically, the pulse duration of the pulses output by melt laser 30 is less than 100 μs; and for melting fine features, the pulses are even shorter, for example less than μs. Depending on the composition of the droplets and the desired melt depth, the duration of each pulse may even be less than 1 μs. The pulse energies are typically in the range of 0.1 μJ up to 100 μJ, depending on the materials and trace dimensions. The use of short, intense laser pulses is beneficial both in reducing heat transfer to substrate 24 and in reducing oxidation of the metal during the melt process, making it possible for the process to be carried out under ambient atmospheric conditions. The use of short laser pulses is also advantageous in reducing the tendency of the metal in droplets to coalesce into separate balls and lose the desired shape characteristic of trace 22. The time between pulses in the sequence can be long enough for the heat from the previous pulse to dissipate, so that heat accumulation does not become a problem.

To enable the pulse duration to be adjusted for different trace dimensions and melt depths, melt laser 30 may comprise a suitable fiber laser or high-power diode laser, for example. If the laser has a sufficiently wide range of adjustment of pulse duration, down to the nanosecond range, it may also serve as LIFT laser 28.

The figures that follow and the accompanying description present a number of techniques that may be applied in LIFT printing of metal traces in conjunction with controlled laser melting. For the sake of clarity and concreteness, these techniques are described hereinbelow with reference to the elements of system 20. These techniques are by no means limited, however, to the specific system configuration that is shown in FIG. 1; and the principles of the present invention may alternatively be applied in other systems having the necessary capabilities, as will be apparent to those skilled in the art after reading the present description. All such alternative implementations are considered to be within the scope of the present invention.

### Printing Metal Lines of Different Widths and Thickness

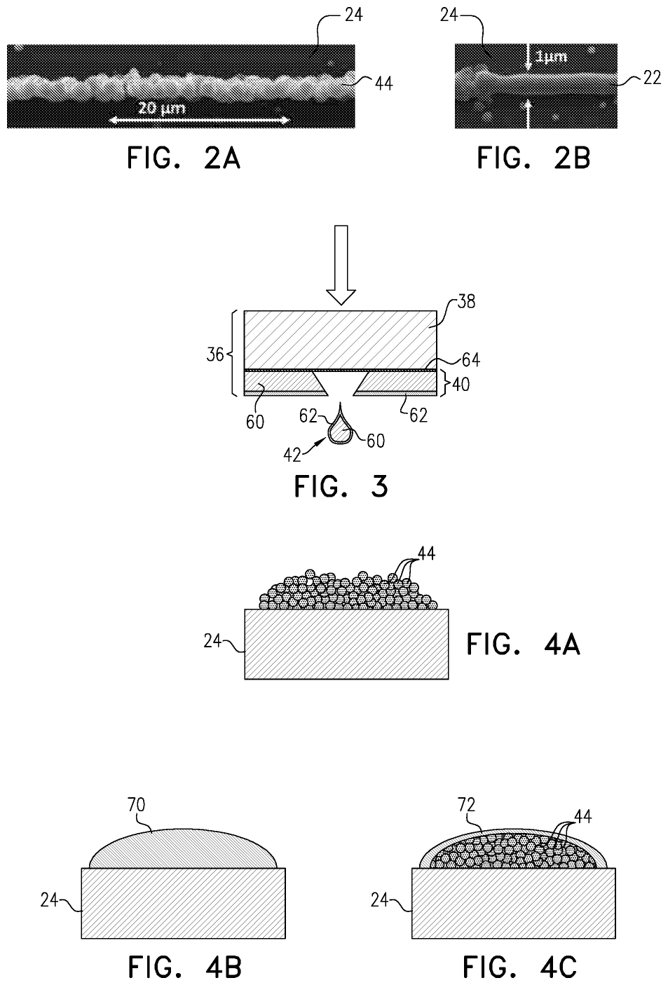

FIG. 2A is a photomicrograph of a line of metal droplets 44 printed on circuit substrate 24 by LIFT laser 28, in accordance with an embodiment of the invention. Droplets 44 are about 1 μm in diameter and are printed in a single row extending along the length of the locus of trace 22, with an overlap of about 50% of the droplet diameter between successive droplets in the sequence. Alternatively, the overlap between successive droplets may be even less than 50% when a very narrow trace is desired.

FIG. 2B is a photomicrograph of trace 22 following laser melting by melt laser 30, in accordance with an embodiment of the invention. A sequence of overlapping laser pulses has scanned over droplets 44, causing them to coalesce into the unitary trace 22 that is shown in this figure, with a line width on the order of 1 μm. The optimal laser pulse parameters to achieve this sort of uniform metal trace depend on the materials and geometrical dimensions that are involved and can be optimized in each case by computation and empirical trial and error.

FIG. 3 is a schematic sectional view of donor assembly 36, illustrating ejection of molten droplet 42 from donor film 40 under laser irradiation, in accordance with an embodiment of the invention. This embodiment is directed to solving problems of poor adhesion between droplets 44 and substrate 24, which can occur particularly in printing very fine traces and in printing on smooth substrates, such as glass.

To address this problem, donor film 40 comprises an adhesion film 62 overlying a primary metal donor film 60 on donor substrate 38. For example, assuming film 60 comprises copper, which is a good conductor but may not adhere well to dielectric substrates, adhesion film 62 may comprise another metal, which oxidizes more quickly than copper, such as titanium, tin, bismuth, or alloys of these metals. Optionally, an intermediate layer 64 is also deposited between donor substrate 38 and primary metal donor film 60 in order to enhance adhesion of the donor film to the donor substrate and reduce reflection of the laser energy at the substrate/film interface. In the present embodiment, primary metal donor film is typically between 50 and 700 nm thick, while adhesion film is thinner, for example between 50 and 200 nm thick.

As shown in FIG. 3, when a laser pulse strikes donor film 40, the metal in adhesion film 62 forms an outer layer over droplet 42, surrounding the primary metal from film 60. This outer layer adheres to circuit substrate 24 upon impact of the molten droplet on the circuit substrate. Because of the speed of the jetting process, the outer layer will not mix substantially into the metal core of droplet 42 while the droplet is in flight. As an alternative to this approach, however, donor film 40 may comprise an alloy with enhanced adhesion properties. Additionally or alternatively, the surface of substrate may be roughened or otherwise prepared to improve adhesion before LIFT jetting.

FIG. 4A is a schematic sectional view of an aggregation of metal droplets 44 deposited on substrate 24 in a LIFT process, defining a circuit trace in accordance with an embodiment of the invention. In this embodiment, the trace is wider and deeper than in the example shown in FIGS. 2A/B.

FIG. 4B is a schematic sectional view of a circuit trace 70 formed by full laser melting of the aggregation of metal droplets 44 that is shown in FIG. 4A, in accordance with an embodiment of the invention. In this case, melt laser 30 applies sufficient energy to hardened droplets 44 in order to melt the entire volume of the hardened droplets in trace 70. This approach is beneficial in maximizing the mechanical integrity and thermal conductivity and in minimizing the electrical resistance of the trace, but it should be applied with care in order to avoid damage to circuit substrate 24 and surrounding structures. In one embodiment (not shown in the figures), beam deflector 46 directs the beam from melt laser 30 to impinge on the volume of droplets 44 over a range of angles of incidence in order to achieve more uniform melting.

FIG. 4C is a schematic sectional view of a circuit trace formed by partial laser melting of the aggregation of metal droplets 44 that is shown in FIG. 4A, in accordance with an alternative embodiment of the invention. In this case, melt laser 30 applies sufficient energy to the hardened droplets to melt only an outer layer of the hardened droplets, without melting the entire volume of the hardened droplets along the length of the trace. This outer layer forms a protective skin 72, which encloses the volume of hardened droplets 44 within the conductive trace. Skin 72 enhances the mechanical and electrical integrity of the trace and its resistance to etching and corrosion. This approach requires a much smaller investment of laser energy, and thus can increase the process throughput while reducing the risks of damage to substrate 24 and deformation of the trace, relative to full melting of the volume of the trace. In one embodiment, the laser beam that is used in the melting process is focused to a spot size smaller than the width of the trace and is scanned over the surface of the trace until the entire area has been covered.

The following table lists examples of process parameters that can be used in controlled laser melting of LIFT-deposited metal traces of various dimensions. In these examples, droplets 44 comprise copper, and the aggregations of the droplets on substrate 24 have the general form shown in FIG. 4A. The number of melt laser pulses applied to each location along the trace in each case can be chosen depending on the desired melt depth, which can range from about 1 μm (as in FIG. 4C) to the full thickness of the trace (as in FIG. 4B).

TABLE I
EXAMPLES OF CONTROLLED LASER MELTING

| | | Pulse | Laser | | | |
|---|---|---|---|---|---|---|
| Trace | Laser | repetition | spot | Pulse | Pulse | Pulse |
| width | wavelength | rate | size | width | pitch | energy |
| 20-40 | Near infrared | 20 | 20 | 250 | 0.5-2 | 15-30 |
| μm | | kHz | μm | ns | μm | μJ |
| 20-40 | Near infrared | 40 | 20 | 1-2 | 0.5-2 | 20-40 |
| μm | | kHz | μm | μs | μm | μJ |
| 7-12 | Near infrared | 20 | 20 | 0.5-2 | 0.5 | 12-25 |
| μm | | kHz | μm | μs | μm | μJ |
| 20 | Visible | 20 | 20 | 600 | 1 | 30-45 |
| μm | (532 nm) | kHz | μm | ns | μm | μJ |
| 5-10 | Near infrared | 20 | 7 | 0.5-2 | 0.5 | 5-10 |
| μm | | kHz | μm | μs | μm | μJ |

The above examples illustrate the broad applicability and range of controllable parameters offered by the present techniques, particularly in forming stable narrow traces, which are difficult or impossible to fabricated by other techniques. The pulse widths can be chosen depending on the depth of melting, with the possibility of performing multiple LIFT/melt cycles when full melting of a thick trace is desired. The pulse pitch and repetition rate can also affect the overall thermal profile and thus influence the depth of melting. The laser spot size is generally chosen to roughly match the width of the trace. The laser wavelength can be chosen, as well, such that the laser energy is well absorbed by the trace but not by the substrate, thereby minimizing damage to the substrate when the laser spot extends over an area wider than the trace.

### Fabrication and Repair of Circuit Elements

Referring back to FIG. 1, in some embodiments the locus in which trace 22 is to be printed comprises a gap between a pair of terminals on the circuit substrate. For example, control circuitry 52 may identify such a gap by analyzing images captured by inspection module 54 of circuit substrate 24. Control circuitry 52 then directs laser module 26 to eject molten droplets 42 from donor film 40 onto substrate 24 so as to fill the gap. In some embodiments, the gap thus identified may be due to a defect, such as a misformed or open circuit trace that is detected on circuit substrate 24. In this case, before filling the gap, the defective trace and the underlying substrate may be cleaned and prepared, for example using laser ablation as described in the above-mentioned Korean Patent Application Publication KR20150070028. This preparation may include shaping the ends of the circuit trace that are adjacent to the gap in order to form well-defined terminals to which droplets 42 will adhere. The defect is then repaired by depositing molten droplets 42 in the gap between the terminals, and then directing the beam of melt laser 30 to melt hardened droplets 44.

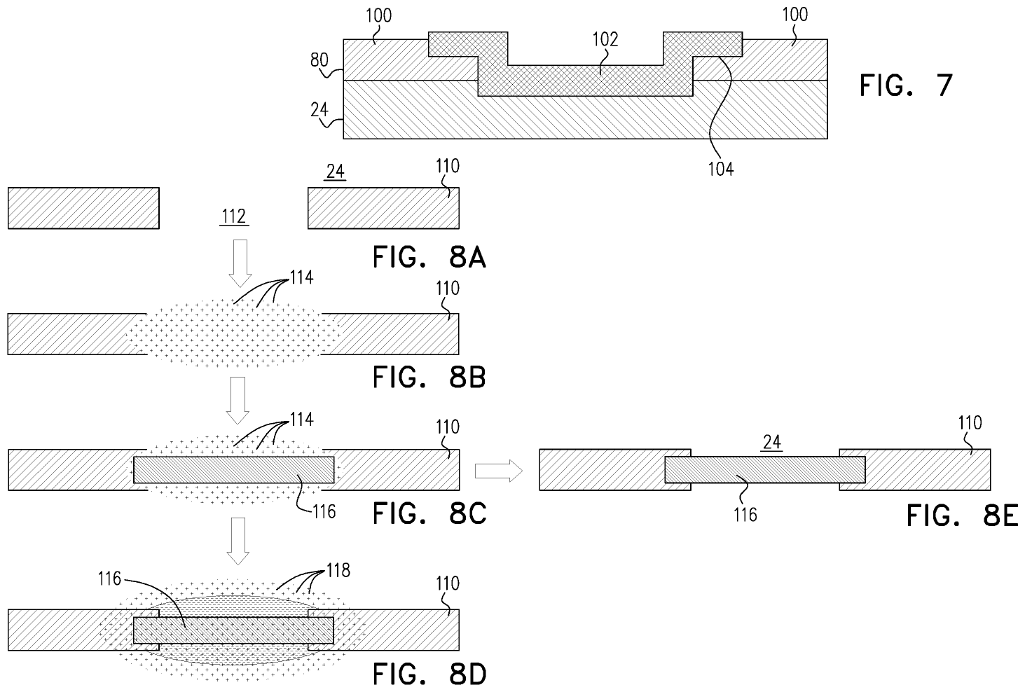

In other embodiments, circuit traces containing gaps are intentionally formed on circuit substrate 24, for example by photolithographic techniques. These gaps can then be filled by LIFT printing with a different material from the circuit traces, for example a resistive material such as NiCr. This process, which is illustrated in FIG. 7, can be used to produce circuit components such as resistors and strain gauges.

FIGS. 5A-5C are schematic sectional views showing stages in a process of filling a gap 82 in a circuit trace, in accordance with an embodiment of the invention. FIG. 5A shows an aggregation of hardened metal droplets 44 deposited by a LIFT process in a gap 82 in a circuit trace 80. It is assumed in this case that gap 82 was created due to a defect in the initial fabrication of trace 80. The edges of gap 82 have been squared off to create well-defined terminals, including a stairstep shape at the edges of the gap. This sort of preprocessing enables uniform deposition of droplets 44 in the gap and good electrical contact between the droplets and the terminals. In this example, droplets 44 have been deposited in a single LIFT deposition step to fill the entire depth of gap 82.

FIG. 5B illustrates the application of a laser melting process to the aggregation of droplets 44. A pulsed beam 84 from melt laser 30 is focused onto the outer surface of the aggregated droplets and scans across gap 82, as indicated by an arrow 86.

FIG. 5C shows circuit trace 80 formed by the laser melting process of FIG. 5B. An upper layer 88 of droplets 44 has melted and bonded to the metal of trace 80, forming a skin that covers the underlying hardened droplets 44. The depth of layer 88 is determined by the intensity and scan pattern of laser beam 84.

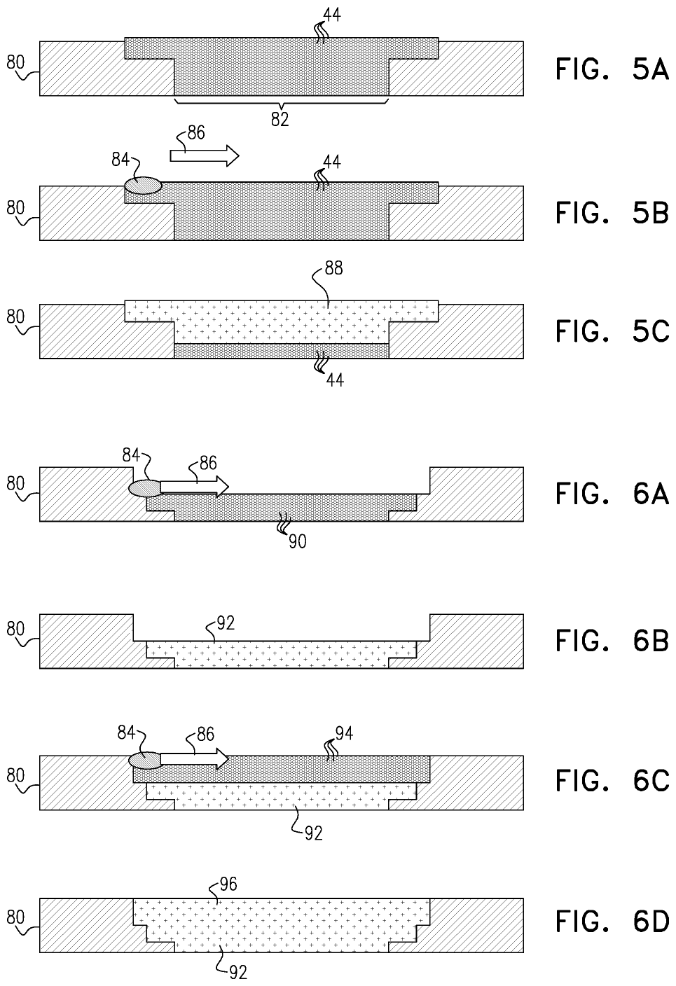

FIGS. 6A-6D are schematic sectional views showing stages in a process of filling a gap in circuit trace 80, in accordance with another embodiment of the invention. FIG. 6A illustrates the application of a laser melting process to an aggregation of metal droplets 90 deposited by a LIFT process in the gap in circuit trace 80. In this case, a layered approach is applied, so that droplets 90 do not fill the entire depth of the gap but rather form a first layer on the circuit substrate. Laser beam 84 is scanned across the gap in order to melt the hardened droplets in this first layer.

FIG. 6B shows the partial circuit trace formed by the laser melting process of FIG. 6A. In this example, the entire depth of droplets 90 has been melted by laser beam 84 so as to form a lower layer 92 of the conductive trace within the gap in circuit trace 80.

FIG. 6C illustrates the application of the laser melting process, by scanning of beam 84, to a further aggregation of metal droplets 94. Droplets 94 are deposited by the LIFT process over lower layer 92, and laser beam 84 is then scanned over this added aggregation of droplets 94 to melt the hardened droplets.

FIG. 6D shows the full circuit trace formed by the laser melting process of FIG. 6C. The controlled laser melting process of FIG. 6C has formed an upper layer 96 of the conductive trace over lower layer 92 so as to fill the gap in trace 80 and thus complete the trace. This multi-layered approach is useful in ensuring that the trace is fully melted and coalesces into a bulk material through its entire depth, while reducing the heat dissipation into trace 80 and substrate 24 (and thus mitigating possible thermal damage). Although FIGS. 6A-D show only a two-layer process for the sake of simplicity, the principles of the present technique can be applied in creating three or more layers, as well, depending on the required trace thickness.

FIG. 7 is a schematic sectional view of a heterogeneous circuit trace printed by a LIFT process, in accordance with an embodiment of the invention. In this embodiment, trace 80 comprises a first metal, for example copper, which is etched or ablated to define terminals 100. Donor film 40 comprises a different metal of a different composition from the first metal, for example NiCr. LIFT laser 28 is operated to deposit droplets of NiCr into the gap between terminals 100. Melt laser 30 then operates not only to cause the NiCr droplets to melt and coalesce into a trace 102, but also to melt at least an upper layer of terminals 100 so as to form heterogeneous metal bonds at the terminals. These bonds are useful in creating metal-to-metal contacts with low resistance and high mechanical strength. As noted earlier, trace 102 may serve, for example, as an embedded resistor or strain gauge.

In similar fashion, even when the trace and terminals comprise the same metal, the operation of melt laser 30 is useful in forming homogeneous metal bonds between the trace and terminals. As in the case of heterogeneous bonds, these metal bonds enhance mechanical strength and resistance to etching and corrosion, as well as reducing electrical resistance.

The following table lists examples of process parameters that can be used in controlled laser melting of LIFT-deposited NiCr traces, which interface with copper circuit traces as shown in FIG. 7:

TABLE II
EXAMPLES OF CONTROLLED LASER
MELTING OF NICR TRACES

| | | Pulse | Laser | | | |
|---|---|---|---|---|---|---|
| Trace | Laser | repetition | spot | Pulse | Pulse | Pulse |
| width | wavelength | rate | size | width | pitch | energy |
| 10 | Visible | 1000 | 20 | 600 | 0.5-1 | 20-40 |
| μm | (532 nm) | Hz | μm | ns | μm | μJ |
| 10 | Visible | 1000 | 20 | 600 | 10 | 50-75 |
| μm | (532 nm) | Hz | μm | ns | μm | μJ |

FIGS. 8A-8E are schematic top views of a circuit trace 110 on substrate 24 showing successive steps in a LIFT-based process of repairing a gap 112 in the circuit trace, in accordance with an alternative embodiment of the invention. FIG. 8A shows gap 112 before the LIFT process is initiated. In this case, as shown in FIG. 8B, droplets 114 are deposited by the LIFT process over an area that is wider than gap 112. This sort of deposition pattern will be created, for example, when LIFT laser 28 emits shorter pulses, for example in the picosecond range, with higher peak power, so that each pulse causes many sub-micron droplets to be ejected toward substrate 24. Operation in this regime can be advantageous in that the hardened droplets are smaller and may adhere better to the substrate, but the directionality of droplet ejection is less accurate.

In order to reduce the width of the area covered by droplets 114, melt laser 30 is applied to melt only the hardened droplets that have been deposited on substrate 24 within the predefined width of the locus of the trace. Thus, as shown in FIG. 8C, a trace area 116 melts and coalesces to form a solid trace, which bonds to circuit trace 110. In order to increase the thickness of the LIFT-deposited trace, the LIFT step may be repeated in order to deposit one or more additional layers of droplets 118 over the area of gap 112, as shown in FIG. 8D. After each such step, the controlled laser melting step of FIG. 8C is repeated to melt and coalesce the additional droplets within trace area 116 (but not outside it).

Once the metal in trace area 116 has reached the desired depth, an etching process is applied to circuit substrate 24 in order to remove the hardened droplets that were deposited on the circuit substrate outside trace area 116. This step may be carried out, for example, using methods of chemical etching or galvanic etching that are known in the art, because the separate droplets outside area 116 have large surface areas relative to their volume and are thus more susceptible to the etching process. Alternatively, the hardened droplets may be removed by laser ablation. The clean trace following the etching step is shown in FIG. 8E

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A method for circuit fabrication, comprising:
defining a locus of a conductive trace to be formed on a circuit substrate; ejecting molten droplets of a metal from a donor substrate in proximity to the circuit substrate onto the defined locus by a process of laser-induced forward transfer (LIFT), whereby the molten droplets adhere to and harden on the circuit substrate along a length of the defined locus; and
after the molten droplets have hardened, directing a laser beam toward the defined locus with sufficient energy to cause the metal in the hardened droplets to melt and coalesce into a bulk layer extending along the length of the defined locus.

2. The method according to claim 1, wherein the donor substrate is transparent and has opposing first and second surfaces, and a donor film comprising the metal is disposed on the second surface such that the donor film is in proximity to the defined locus, and
wherein ejecting the molten droplets comprises directing pulses of laser radiation to pass through the first surface of the donor substrate and impinge on the donor film so as to induce ejection from the donor film onto the defined locus of the molten droplets of the metal.

3. The method according to claim 2, wherein directing the pulses of laser radiation in the process of LIFT and directing the laser beam toward the defined locus comprise using a single laser having a variable pulse duration for both ejecting the molten droplets and melting the metal in the hardened droplets.

4. The method according to claim 2, wherein the donor film comprises a first metal, and wherein an adhesion film, comprising a second metal is disposed over the donor film on the donor substrate, so that the second metal forms an outer layer over the molten droplets of the first metal, and the outer layer adheres to the circuit substrate upon impact of the molten droplets on the circuit substrate.

5. The method according to claim 4, wherein the first metal comprises copper, and wherein the second metal is selected from a group consisting of titanium, tin, bismuth, and alloys thereof.

6. The method according to claim 1, wherein ejecting the molten droplets and directing the laser beam toward the defined locus comprise:
ejecting a first layer of the molten droplets onto the circuit substrate and directing the laser beam to melt the hardened droplets in the first layer so as to form a lower layer of the conductive trace; and
ejecting at least a second layer of the molten droplets onto the lower layer and directing the laser beam to melt the hardened droplets in the at least second layer so as to complete the conductive trace.

7. The method according to claim 1, wherein directing the laser beam comprises applying sufficient energy to the hardened droplets, using the laser beam, to melt an entire volume of the hardened droplets in the conductive trace.

8. The method according to claim 1, wherein directing the laser beam comprises applying sufficient energy to the hardened droplets, using the laser beam, to melt only an outer layer of the hardened droplets, without melting an entire volume of the hardened droplets along the length of the defined locus.

9. The method according to claim 1, wherein directing the laser beam comprises directing a sequence of pulses of laser energy to impinge on the hardened droplets along the length of the defined locus.

10. The method according to claim 9, wherein each of the pulses has a pulse duration that is less than 10 μs.

11. The method according to claim 9, wherein directing the one or more pulses comprises scanning the laser beam along the locus, such that each of the pulses has a predefined overlap with a preceding pulse in the sequence.

12. The method according to claim 1, wherein ejecting the molten droplets comprises depositing the molten droplets on the circuit substrate in a single row extending along the length of the defined locus, whereby the conductive trace is formed by melting of the single row, wherein each of the molten droplets overlaps a preceding molten droplet in the single row by no more than 50% of a diameter of the molten droplet.

13. The method according to claim 1, wherein defining the locus comprises identifying a gap between first and second terminals on the circuit substrate, and wherein ejecting the molten droplets comprises depositing the molten droplets so as to fill the gap.

14. The method according to claim 13, wherein the first and second terminals comprise a first metal, and the molten droplets comprise a second metal, of a different composition from the first metal, and wherein directing the laser beam comprises melting the first and second metals so as to form heterogeneous metal bonds at the first and second terminals.

15. The method according to claim 13, wherein identifying the gap comprises detecting a defect in a circuit trace that has been formed on the circuit substrate, and wherein the defect is repaired by depositing the molten droplets and then directing the laser beam to melt the hardened droplets.

16. An apparatus for fabrication of a conductive trace on a circuit substrate, the apparatus comprising:
a deposition module, which is configured to eject molten droplets of a metal from a donor substrate in proximity to the circuit substrate onto a defined locus of the conductive trace by a process of laser-induced forward transfer (LIFT), whereby the molten droplets adhere to and harden on the circuit substrate along a length of the defined locus; and
a laser module, which is configured to direct a laser beam toward the defined locus with sufficient energy to cause the metal in the hardened droplets to melt and coalesce into a bulk layer extending along the length of the defined locus.

17. The apparatus according to claim 16, wherein the donor substrate is transparent and has opposing first and second surfaces, and a donor film comprising the metal is disposed on the second surface such that the donor film is in proximity to the defined locus, and
wherein the laser module is configured to direct pulses of laser radiation to pass through the first surface of the donor substrate and impinge on the donor film so as to induce ejection from the donor film onto the defined locus of the molten droplets of the metal.

18. The apparatus according to claim 17, wherein the laser module comprises a single laser having a variable pulse duration for both directing the pulses of laser radiation in the process of LIFT and directing the laser beam to melt the metal in the hardened droplets.

19. The apparatus according to claim 16, wherein the deposition module and the laser module are configured to eject a first layer of the molten droplets onto the circuit substrate and to direct the laser beam to melt the hardened droplets in the first layer so as to form a lower layer of the conductive trace, and to eject at least a second layer of the molten droplets onto the lower layer and direct the laser beam to melt the hardened droplets in the at least second layer so as to complete the conductive trace.

20. The apparatus according to claim 16, wherein the laser module is configured to apply sufficient energy to the hardened droplets, using the laser beam, to melt an entire volume of the hardened droplets in the conductive trace.

21. The apparatus according to claim 16, wherein the laser module is configured to apply sufficient energy to the hardened droplets, using the laser beam, to melt only an outer layer of the hardened droplets, without melting an entire volume of the hardened droplets along the length of the defined locus.

22. The apparatus according to claim 21, wherein the laser module is configured to direct a sequence of pulses of laser energy to impinge on the hardened droplets along the length of the defined locus.

23. The apparatus according to claim 22, wherein each of the pulses has a pulse duration that is less than 10 μs.

24. The apparatus according to claim 22, wherein the laser module is configured to scan the laser beam along the locus, such that each of the pulses has a predefined overlap with a preceding pulse in the sequence, wherein each of the molten droplets overlaps a preceding molten droplet in the single row by no more than 50% of a diameter of the molten droplet.

25. The apparatus according to claim 16, wherein the deposition module is configured to deposit the molten droplets on the circuit substrate in a single row extending along the length of the defined locus, whereby the conductive trace is formed from the single row.

26. The apparatus according to claim 16, and comprising control circuitry, which is configured to identify a gap between first and second terminals on the circuit substrate, and to control the deposition module to deposit the molten droplets so as to fill the gap.

27. The apparatus according to claim 26, wherein the first and second terminals comprise a first metal, and the molten droplets comprise a second metal, of a different composition from the first metal, and wherein the laser module is configured to direct the laser beam to melt the first and second metals so as to form heterogeneous metal bonds at the first and second terminals.
